(19) United States
(12) Patent Application Publication
(10) Pub. No.: US 2013/0193511 A1
(43) Pub. Date: Aug. 1, 2013

(54) VERTICAL TRANSISTOR STRUCTURE

(71) Applicants: Hsuan-Yu FANG, Taichung City (TW); Wei-Chih Liu, Taichung City (TW); Yu-Ling Huang, Taichung City (TW); Meng-Hsien Chen, Taichung City (TW); Chun-Chiao Tseng, Taichung City (TW); Chung-Yung Ai, Taichung City (TW); Yu-Shan Hsu, Taichung City (TW); Wei-Che Chang, Taichung City (TW); Chun-Hua Huang, Taichung City (TW); Kazuaki Takesako, Taichung City (TW); Tomohiro Kadoya, Taichung City (TW); Wen Kuei Hsu, Taichung City (TW); Hirotake Fujita, Taichung City (TW); Yukihiro Nagai, Taichung City (TW); Chih-Wei Hsiung, Taichung City (TW); Yoshinori Tanaka, Taichung City (TW)

(72) Inventors: Hsuan-Yu FANG, Taichung City (TW); Wei-Chih Liu, Taichung City (TW); Yu-Ling Huang, Taichung City (TW); Meng-Hsien Chen, Taichung City (TW); Chun-Chiao Tseng, Taichung City (TW); Chung-Yung Ai, Taichung City (TW); Yu-Shan Hsu, Taichung City (TW); Wei-Che Chang, Taichung City (TW); Chun-Hua Huang, Taichung City (TW); Kazuaki Takesako, Taichung City (TW); Tomohiro Kadoya, Taichung City (TW); Wen Kuei Hsu, Taichung City (TW); Hirotake Fujita, Taichung City (TW); Yukihiro Nagai, Taichung City (TW); Chih-Wei Hsiung, Taichung City (TW); Yoshinori Tanaka, Taichung City (TW)

(21) Appl. No.: 13/358,823

(22) Filed: Jan. 26, 2012

(51) Int. Cl. H01L 27/088

(52) U.S. Cl. 257/334; 257/E27.06

(57) ABSTRACT

A vertical transistor structure comprises a substrate, a plurality of pillars formed on the substrate and spaced from each other, a plurality of trenches each formed between two adjacent pillars, a protection layer formed on the surface of a first side wall and the surface of a second side wall of the trench, a first gate and a second gate respectively formed on the protection layer of the first side wall and the second side wall, and a separation layer covering a bottom wall of the trench. The present invention uses the separation layer functioning as an etch stopping layer to the first gate and the second gate while being etched. Further, thickness of the separation layer is used to control the distance between the bottom wall and the first and second gates and define widths of the drain and the source formed in the pillar via ion implantation.

### FIELD OF THE INVENTION

The present invention relates to a transistor structure, particularly to a vertical transistor structure.

### BACKGROUND OF THE INVENTION

With advance of semiconductor technology, electronic elements become smaller and smaller, and the performance thereof is also enhanced continuously. Normally, the technological developments of semiconductor are addressed to reducing transistor size and increasing circuit integration. Reducing transistor size can improve switching speed, power consumption and performance. Precision etch processes and apparatuses are necessary to promote the yield of products when the size of electronic elements is reduced.

The feature size of IC has decreased from 60 nm to 40 nm, and is still decreasing for the time being. At the same time, the size of transistors has advanced from 6F2 to 4F2, and the design of transistors has also evolved from a planar structure to a vertical structure. For example, a U.S. publication No. 2010/0038709 discloses a “Vertical Transistor and Array with Vertical Transistors” to greatly reduce the area occupied by a transistor on a wafer, wherein many photomasks are used to implement development and etch steps. However, the complicated procedures thereof not only increase fabrication time but also decrease the yield. Besides, the vertical transistor technology still has to overcome a problem of GIDL (Gate-Induced Drain Leakage), which results from overlap of the gate and the source/drain.

Refer to FIG. 1 for a conventional vertical transistor structure, which has a plurality of pillars 2 formed on a substrate 1 and spaced from each other and a plurality of trenches 3 each formed between two adjacent pillars 2. In an N-type semiconductor vertical transistor structure, two ends of each pillar 2 are implanted with N-type ion to form a source 4 and a drain 5. Two separate gates 6 are formed on two side walls of each trench 3 to control the electric conduction of the two pillars 2 at two sides of the trench 3. The gate 6 is formed on the bottom wall 7 of the trench 3. In order to avoid the overlap of the gate 6 and the source 4, the source 4 must be formed in a region of the substrate 1, which is below the pillar 2. Thus, ion is likely to diffuse in the substrate 1. Consequently, the ion distributed in the substrate 1 is likely to cause mutual influence between adjacent pillars 2 and result in current leakage. Therefore, the conventional vertical transistor technology still has room to improve.

### SUMMARY OF THE INVENTION

The primary objective of the present invention is overcome the conventional problem that the position of the gate and the aspect ratio are hard to precisely control in a vertical transistor structure.

To achieve the above-mentioned objective, the present invention proposes a vertical transistor structure, which comprises a substrate, a plurality of pillars formed on the substrate and spaced from each other, a protection layer, a first gate, a second gate, and a separation layer. A trench is formed between two adjacent pillars. Each trench has a first side wall and a second side wall adjacent to two different pillars and a bottom wall vertical to the first side wall and the second side wall and adjacent to the substrate. Two ends of each pillar are implanted with ion to form a drain and a source. The protection layer is formed on the surface of the first side wall and the surface of the second side wall. The first gate and the second gate are respectively formed on the protection layer on the first and second side walls. The first and second gates are spaced from each other by a separation distance without contacting to form a recess between them. The separation layer covers the bottom wall. The separation layer has one side which is far from the bottom wall connecting with the first and second gates. The thickness of the separation layer determines the distance separating the first/second gate and the bottom wall.

In summary, the present invention arranges the separation layer between the bottom wall and the first/second gate to control the distance between the bottom wall and the first/second gate. Therefore, the source or drain, which is nearer to the substrate, can be formed inside the pillar to prevent the ion implanted in the source or drain from diffusing to the substrate and causing current leakage.

### BRIEF DESCRIPTION OF THE DRAWINGS

FIG. 1 schematically shows a conventional vertical transistor structure;

FIG. 2 schematically shows a vertical transistor structure according to one embodiment of the present invention;

FIG. 3 shows a flowchart of a method for fabricating a vertical transistor structure according to one embodiment of the present invention; and

FIGS. 4A-4H show steps of a method for fabricating a vertical transistor structure according to one embodiment of the present invention.

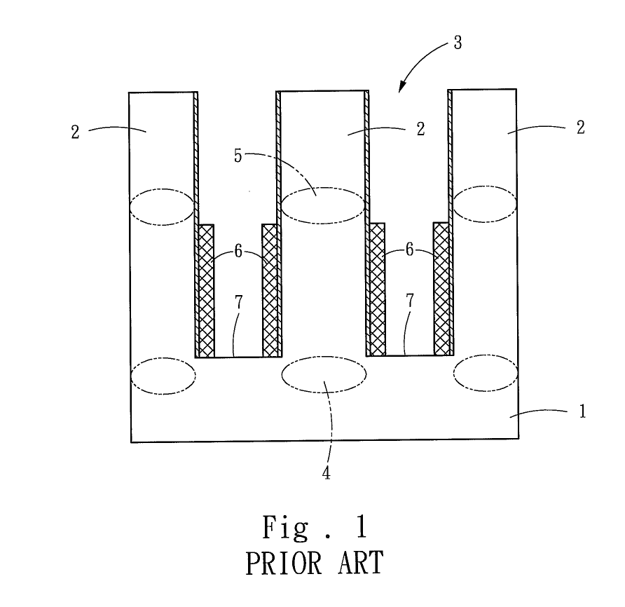

### DETAILED DESCRIPTION OF THE PREFERRED EMBODIMENTS

The technical contents of the present invention are described in detail in cooperation with the drawings below.

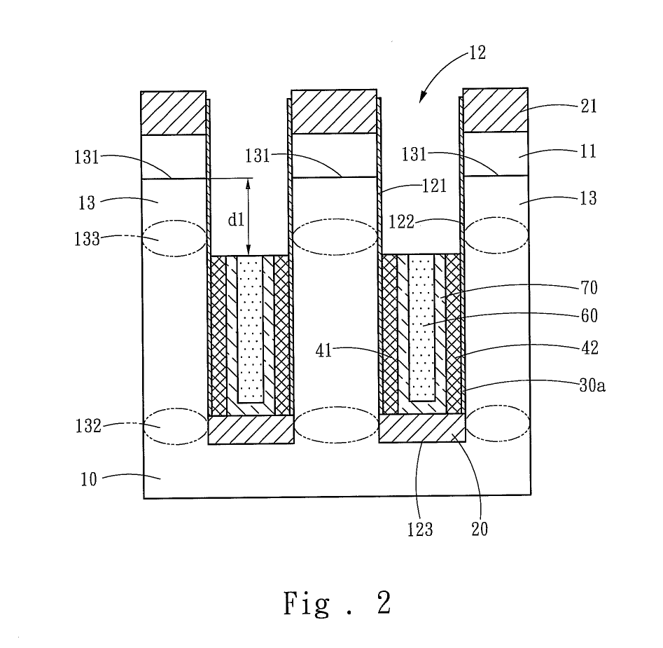

Refer to FIG. 2. The present invention proposes a vertical transistor structure, which comprises a substrate 10, a plurality of pillars 13 formed on the substrate 10 and spaced from each other, a protection layer 30a, a first gate 41, a second gate 42, and a separation layer 20. A trench 12 is formed between two adjacent pillars 13. Each trench 12 has a first side wall 121 and a second side wall 122 adjacent to two different pillars 13 and a bottom wall 123 vertical to the first side wall 121 and the second side wall 122 and adjacent to the substrate 10. Two ends of each pillar 13 are implanted with ion to form a drain 133 and a source 132. The protection layer 30a is formed on the surfaces of the first and second side walls 121 and 122. The first and second gates 41 and 42 are respectively formed on the protection layer 30a of the first and second side walls 121 and 122. The first and second gates 41 and 42 do not contact each other but are separated by a separation distance. In the embodiment, an insulating material 60 is filled between the first and second gates 41 and 42 to prevent from electric conduction between the first and second gates 41 and 42. The insulating material 60 can be oxide such as silicon dioxide, or nitride such as silicon nitride. The separation layer 20 covers the bottom wall 123. The separation layer 20 has one side which is far from the bottom wall 123 connecting with the first and second gates 41 and 42. The thickness of the separation layer 20 determines the distance between the bottom wall 123 and the first/second gate 41 or 42. Each pillar 13 has a top end 131 far from the substrate 10. The first gate 41 and the second gate 42 are spaced from the top end 131 by an etching distance dl. The thickness of the separation layer 20 and the etching distance dl are used to control the lengths and positions of the first and second gates 41 and 42. Thus are also determined the ion-implant regions for the source 132 and the drain 133 and the distance between the source 132 and the drain 133.

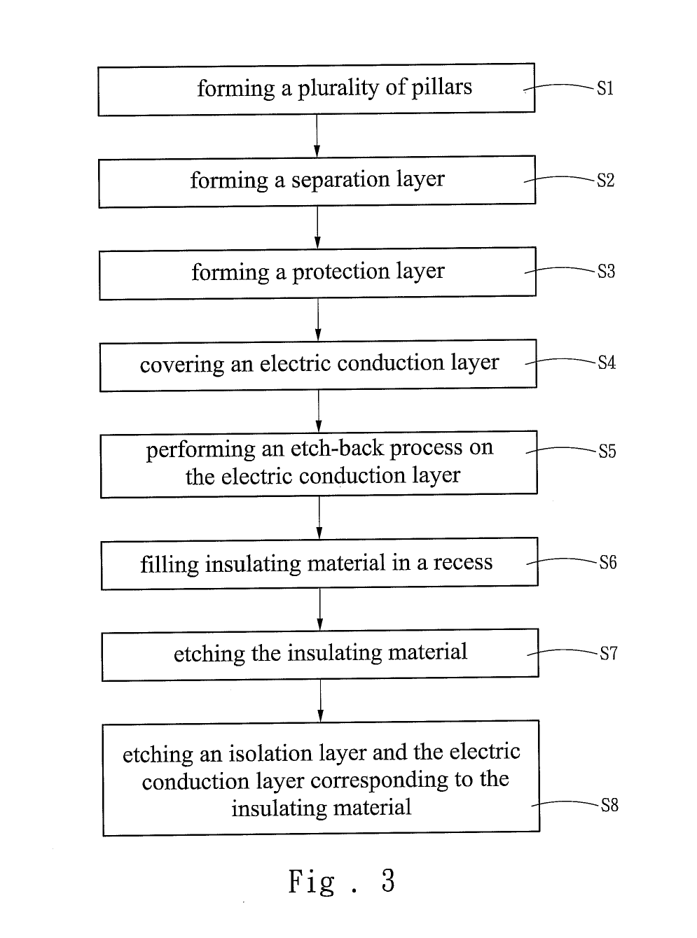

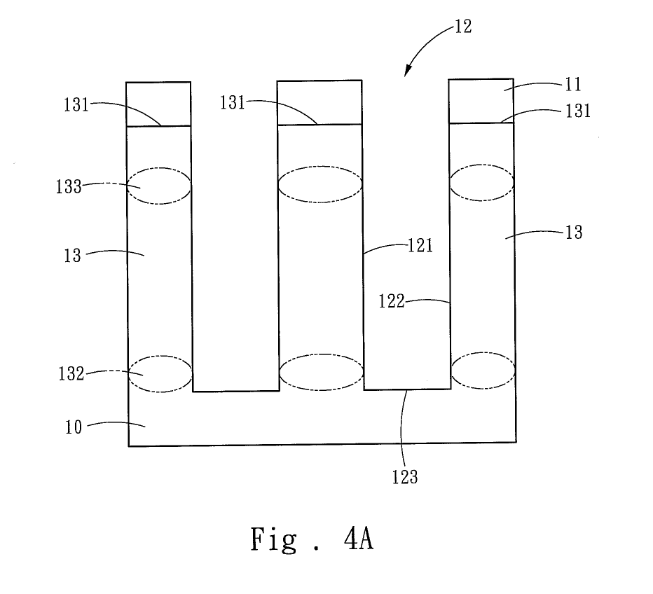

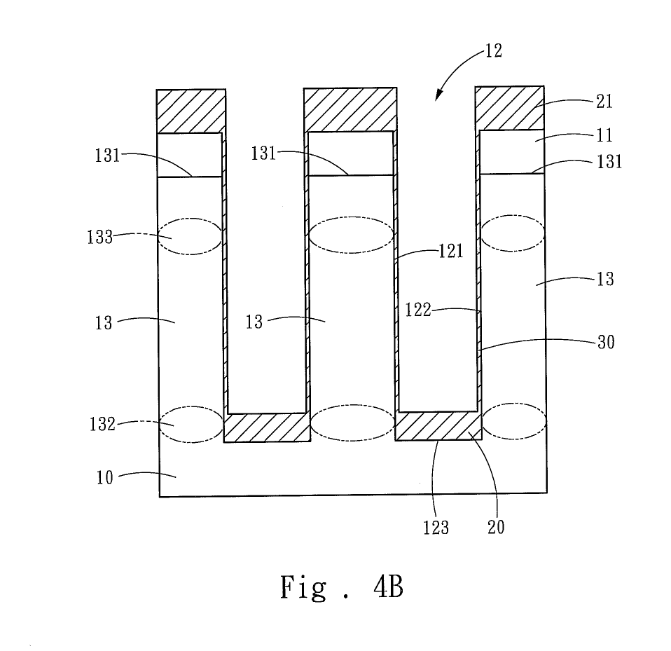

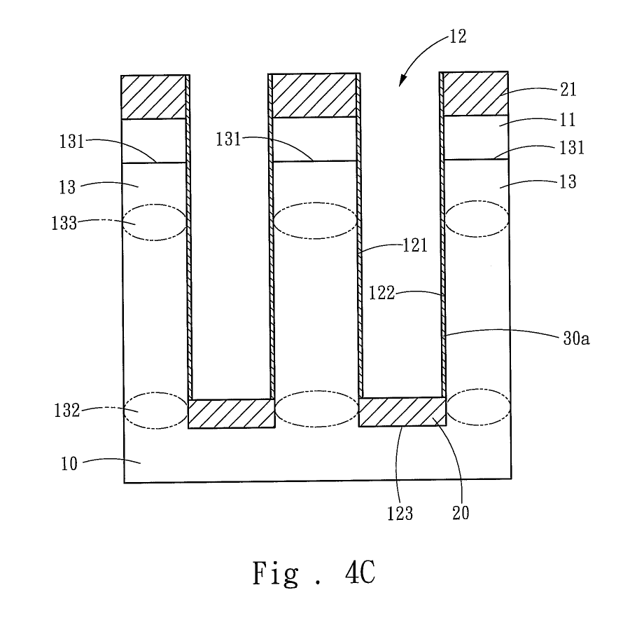

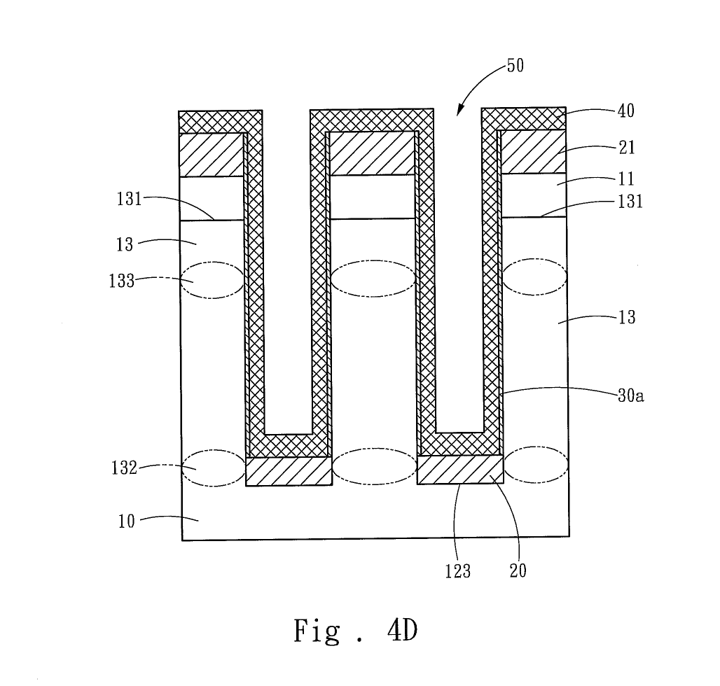

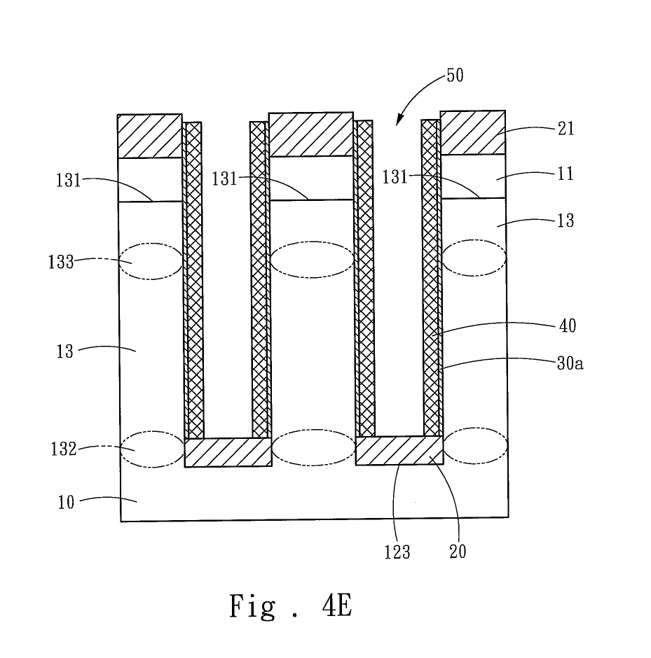

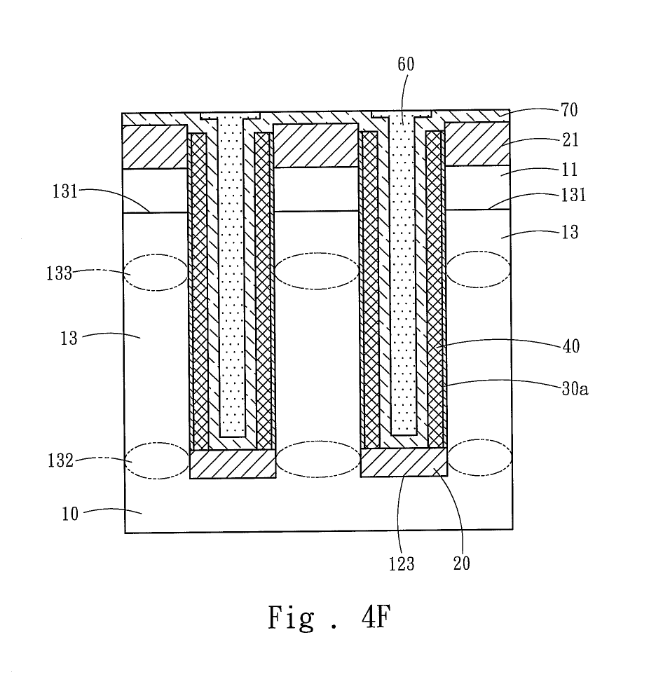

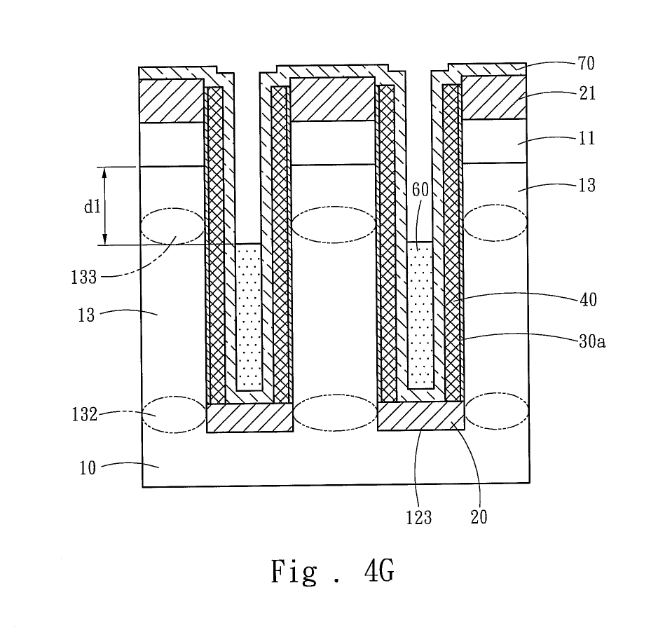

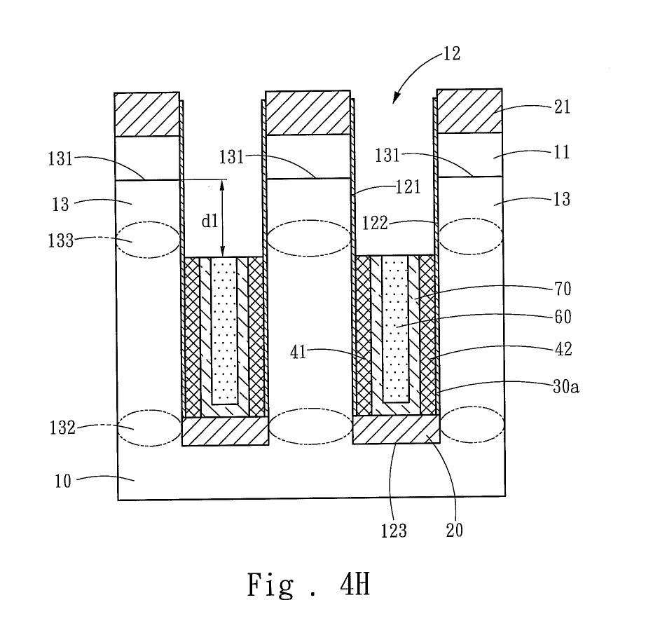

Refer to FIG. 3 and FIGS. 4A-4H. The present invention also proposes a method for fabricating a vertical transistor structure, which comprises the following steps.

Step S1: forming a plurality of pillars 13. Refer to FIG. 4A. A plurality of photoresist layers 11 are formed on a substrate 10. Next, etching is undertaken to form a plurality of trenches 12. The unetched regions thus form the pillars 13. The substrate 10 and the pillars 13 are made of silicon. Each trench 12 has a first side wall 121, a second side wall 122, and a bottom wall 123 connecting to the first and second side walls 121 and 122 and neighboring the substrate 10. In order to fabricate a transistor, ion is respectively implanted into the region of the pillar 13, which is near the photoresist layer 11, and the region of the pillar 13, which is near the substrate 10, to form a drain 133 and a source 132. In an embodiment of an N-type transistor, N-type ion is implanted into the pillar 13, or the pillar 13 is doped with an N-type ion. For the source 132, the ion is not implanted into the substrate 10 but implanted into the region of pillar 13, which is near the substrate 10. Such a measure can effectively inhibit diffusion of the implanted ion and prevent from current leakage.

Step S2: forming a separation layer 20. Refer to FIG. 4B. In one embodiment, the separation layer 20 is deposited on the bottom wall 123 with an anisotropic deposition technology. The separation layer 20 is also deposited on the photoresist layer 11 in this step. The separation layer on the photoresist layer 11 is defined as a top separation layer 21. Because of anisotropic deposition, only a very thin layer is deposited on the first and second side walls 121 and 122. The anisotropic deposition technology may be realized with an HPD (High Density Plasma) method. The separation layer 20 is made of silicon dioxide or silicon nitride.

Step S3: forming a protection layer 30 and a protection layer 30a. Refer to FIG. 4C. In the above-mentioned HDP process, a protection layer 30 is simultaneously deposited on the surfaces of the first and second side walls 121 and 122. However, the density of the protection layer 30 on the first and second side walls 121 and 122 is uneven because of anisotropic deposition of the HDP process. Therefore, the protection layer 30 formed by the HDP process is removed by etching, and a new protection layer 30a is deposited. The protection layer 30a is made of silicon dioxide or silicon nitride. The protection layer 30a is made of a material identical to or different from the material of the separation layer 20.

Step S4: forming an electric conduction layer 40. Refer to FIG. 4D. An electric conduction layer 40 is formed to cover the protection layer 30a, the separation layer 20 and the surface of the top separation layer 21 via an ALD (Atomic Layer Deposition) method or an SFD (Supercritical Fluid Deposition) method. Thereby is formed a recess 50 inside the trench 12. The electric conduction layer 40 is made of tungsten or titanium nitride.

Step S5: performing an etch-back process on the electric conduction layer 40. Refer to FIG. 4E. An anisotropic etch process is performed to remove the electric conduction layer 40 on the top separation layer 21 and on the separation layer 20, whereby the electric conduction layer 40 on the first side wall 121 is effectively parted from the electric conduction layer 40 on the second side wall 122. The separation layer 20 protects the bottom wall 123 from the influence of etching.

Step S6: filling an insulating material 60 in the recess 50. Refer to FIG. 4F. In one embodiment, the insulating material 60 is formed in the recess 50 via an SOD (Spin On Dielectric) method. However, the SOD method is likely to damage the electric conduction layer 40. In order to prevent the electric conduction layer 40 from being damaged during the SOD process, an isolation layer 70 is formed on the electric conduction layer 40 before the insulating material 60 is filled in the recess 50.

Step S7: etching the insulating material 60. Refer to FIG. 4G. The insulating material 60 is etched via a wet-etching method or a dry-etching method until an etching distance dl is obtained. The etching distance dl is the distance between the top end 131 of the pillar 13 and the top of the insulating material 60 being etched.

Step S8: etching the isolation layer 70 and the electric conduction layer 40 corresponding to the insulating material 60. Refer to FIG. 4H. The isolation layer 70 and the electric conduction layer 40, which are exposed on the insulating material 60, are etched away. The remaining electric conduction layers 40 respectively function as a first gate 41 on the first side wall 121 and a second gate 42 on the second side wall 122.

In conclusion, the present invention arranges the separation layer 20 between the bottom wall 123 and the first and second gates 41 and 42 to control the distance between the bottom wall 123 and the first and second gates 41 and 42, whereby the source 132 or the drain 133, which is near the substrate 10, can be formed inside the pillar 13 or in a region near the pillar 13. Thus, the boundary of the pillar 13 inhibits the implanted ion of the source 132 or the source 133 from diffusing in the substrate 10 in a large scale. Then is solved the problem of current leakage. Besides, when the etch-back process is performed on the electric conduction layer 40, the separation layer 20 can also function as an etch stopping layer to prevent the substrate 10 from being excessively etched.

The embodiments described above are only to exemplify the present invention but not to limit the scope of the present invention. Any equivalent modification or variation according to the spirit of the present invention is to be also included within the scope of the present invention.

What is claimed is:

1. A vertical transistor structure, comprising:
a substrate;
a plurality of pillars formed on the substrate and spaced from each other via a trench, the trench including a first side wall and a second side wall adjacent to two different pillars and a bottom wall vertical to the first side wall and the second side wall and adjacent to the substrate, each of the plurality of pillars including two ends respectively formed in a drain and a source via ion implantation;
a protection layer formed on a surface of the first side wall and a surface of the second side wall;
a first gate and a second gate respectively formed on the protection layer of the first side wall and the second side wall, wherein the first gate and the second gate are spaced from each other without contacting to form a recess between them; and
a separation layer covering the bottom wall, wherein the separation layer has one side which is far from the bottom wall connecting with the first gate and the second gate.

2. The vertical transistor structure according to claim 1, wherein the substrate is etched to form a plurality of trenches and pillars.

3. The vertical transistor structure according to claim 1, wherein the protection layer and the separation layer are made of an identical material.

4. The vertical transistor structure according to claim 1, wherein the protection layer and the separation layer are made of oxide or nitride.

5. The vertical transistor structure according to claim 1, wherein the protection layer and the separation layer are fabricated via high density plasma technology.

6. The vertical transistor structure according to claim 1, wherein the recess is filled with insulating material.

7. The vertical transistor structure according to claim 6, wherein the recess and the insulating material are interposed by an isolation layer to isolate the insulating material from the first gate and the second gate.

8. The vertical transistor structure according to claim 6, wherein the pillar has a top end far from the substrate, and wherein the first gate and the second gate are spaced from the top end by an etching distance.
